(19) United States
(12) Patent Application Publication
(10) Pub. No.: US 2024/0339380 A1
(43) Pub. Date: Oct. 10, 2024

(54) SEMICONDUCTOR-TYPE WIND SPEED SENSOR AND METHOD OF MANUFACTURING THE SAME

(71) Applicant: TECH UNIVERSITY OF KOREA Industry Academic Cooperation Foundation, Siheung-si (KR)

(72) Inventor: Chang Kyu KIM, Siheung-si (KR)

(21) Appl. No.: 18/513,108

(22) Filed: Nov. 17, 2023

(30) Foreign Application Priority Data
Apr. 10, 2023 (KR) 10-2023-0047028

(51) Int. Cl. H01L 23/48; G01P 5/12; H01L 23/13

(52) U.S. Cl. CPC H01L 23/481; G01P 5/12; H01L 23/13

(57) ABSTRACT

A semiconductor-type wind speed sensor is provided. The semiconductor-type wind speed sensor includes a substrate including a through hole, a pair of electrodes formed on the substrate, and a metal wire configured to electrically connect the pair of electrodes.

### CROSS-REFERENCES

The following applications and materials are incorporated herein, in their entireties, for all purposes: Korean Patent Application No. 10-2023-0047028 filed on Apr. 10, 2023, in the Korean Intellectual Property Office.

### FIELD

One or more embodiments relate to a semiconductor-type wind speed sensor and a method of manufacturing the same.

### INTRODUCTION

The wind speed has a significant impact on everyday life. Indeed, in the developed industrial society, the number of fields in which work is affected by the wind speed and wind power is increasing, and more accurate measurements are required as the industry progresses. In general, a wind speed sensor refers to a device that detects and calculates the wind speed and displays the wind speed using numerals, to facilitate analyzing of the wind speed.

Regarding such sensors, hot wire-type sensors are widely known. Such a hot wire-type flow velocity sensor heats a metal wire with a diameter of several micrometers (μm), and measures the flow velocity based on a change in electrical resistance of the metal wire due to a change in a temperature of the metal wire by the cooling effect caused by the flow velocity.

For example, the cooling effect may increase as the flow velocity increases, and accordingly, a value of the electrical resistance may increase. Therefore, it is possible to measure the flow velocity by monitoring a change in the value of the electrical resistance.

In addition, as a hot wire-type flow velocity sensor with a higher sensitivity, when a temperature distribution of a hot body by the metal wire changes due to the flow velocity, the change in the temperature distribution is detected by temperature sensor wires mounted on both sides of the metal wire, and the flow velocity may be measured based on a difference between electrical resistance values of both temperature sensor wires.

Such hot wire-type wind speed sensors are used in a large number of fields because it is easy to perform electrical conversion and signal processing. However, since hot wire-type wind speed sensors are greatly affected by the ambient temperature or humidity, errors in measured values may occur.

Due to a high frequency of errors in a wind speed sensor in summer and winter, manufacturing productivity is reduced. Since hot wire-type temperature and wind speed sensors are significantly affected by, in particular, the ambient temperature and humidity, productivity may decrease due to a high incidence of defective products. Accordingly, material and structural supplementation has been needed.

Therefore, research on stable operations of temperature of wind speed sensors and anemometers has been conducted, and as a result, a semiconductor-type wind speed sensor has been developed.

### SUMMARY

One or more embodiments of the present disclosure provide a semiconductor-type wind speed sensor and a method of manufacturing the same.

Specifically, one or more embodiments provide a semiconductor-type wind speed sensor with productivity enhanced due to a simple process and a simple structure, and provide a method of manufacturing the same.

However, goals obtainable from the present disclosure are not limited to the above-mentioned goal, and other unmentioned goals can be clearly understood from the following description by one of ordinary skill in the art to which the present disclosure pertains.

According to an aspect, there is provided a semiconductor-type wind speed sensor including a substrate including a through hole, a pair of electrodes formed on the substrate, and a metal wire configured to electrically connect the pair of electrodes.

According to an embodiment, the through hole may be formed between the pair of electrodes.

According to an embodiment, the metal wire may be formed above the through hole.

According to an embodiment, the metal wire may include at least one of gold (Au), silver (Ag), palladium (Pd), rhodium (Rh), iridium (Ir), osmium (Os), aluminum (Al), nickel (Ni), molybdenum (Mo), platinum (Pt), tungsten (W), and tantalum (Ta).

According to an embodiment, the metal wire may have a diameter of several micrometers (μm) to several millimeters (mm).

According to an embodiment, the substrate may include at least one of silicon (Si), germanium (Ge), selenium (Se), gallium arsenide (GaAs), gallium arsenide phosphide (GaAsP), gallium nitride (GaN), silicon carbide (SiC), zinc sulfide (ZnS), silicon dioxide (SiO₂), polyimide (PI), polyetherimide (PEI), polycarbonate (PC), polyester (PES), polystyrene (PS), polyolefin (PO), polysulfone (PSF), polyarylate (PAR), polyvinyl chloride (PVC), and cellulose ester.

According to an embodiment, the substrate may further include an insulating film formed on the substrate.

According to an embodiment, the insulating film may include at least one of an oxide film, a nitride film, an oxynitride film, a nitride oxide film, a phosphosilicate glass (PSG) film, and a borophosphosilicate glass (BPSG) film.

According to an embodiment, the substrate may further include a mesh material.

According to an embodiment, the substrate may have a thickness of about 50 μm to about 800 μm.

According to an embodiment, the semiconductor-type wind speed sensor may be configured to control a temperature of the metal wire by allowing a current to flow through the metal wire.

According to an embodiment, the semiconductor-type wind speed sensor may be configured to calculate a wind speed from a change in a resistance value of the metal wire due to a change in a temperature of the metal wire caused by an air flow passing through the through hole.

According to an embodiment, in the semiconductor-type wind speed sensor, an area of the through hole may correspond to a range of about 3% to about 70% of an area of the substrate.

According to an embodiment, the semiconductor-type wind speed sensor may further include an adhesive layer on the substrate.

According to another aspect, there is provided a method of manufacturing a semiconductor-type wind speed sensor, the method including preparing a substrate including a through hole, forming a pair of electrodes such that the through hole is between the electrodes, and electrically connecting the pair of electrodes with a wire.

Additional aspects of embodiments will be set forth in part in the description which follows and, in part, will be apparent from the description, or may be learned by practice of the disclosure.

According to embodiments, a semiconductor-type wind speed sensor and a method of manufacturing the same may be provided.

The semiconductor-type wind speed sensor may have a simple structure and may be manufactured by a simple manufacturing method in comparison to existing wind speed sensors. In addition, the semiconductor-type wind speed sensor may measure a speed of wind away from a surface of the semiconductor-type wind speed sensor, thereby providing a measurement value with a high reliability.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a plan view of a semiconductor-type wind speed sensor according to an embodiment; and

FIG. 2 is a front view of a semiconductor-type wind speed sensor according to an embodiment.

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, components, or combinations thereof, but do not preclude the presence or addition of one or more of other features, integers, steps, operations, elements, components, or combinations thereof.

Unless otherwise defined, all terms including technical and scientific terms used herein have the same meaning as commonly understood by one of ordinary skill in the art to which the embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure. In addition, terms such as first, second, A, B, (a), (b), and the like may be used to describe components of the embodiments. These terms are used only for the purpose of discriminating one component from another component, and the nature, the sequences, or the orders of the components are not limited by the terms.

Components included in an embodiment and components having common functions are described using the same names in other embodiments. Unless otherwise mentioned, the descriptions on the embodiments may be applicable to the following embodiments and thus, duplicated descriptions will be omitted for conciseness.

Hereinafter, a semiconductor-type wind speed sensor and a method of manufacturing the semiconductor-type wind speed sensor will be described in detail with reference to embodiments and drawings. However, the present disclosure is not limited to the embodiments and drawings.

According to an embodiment, a semiconductor-type wind speed sensor may include a substrate including a through hole, a pair of electrodes formed on the substrate, and a metal wire configured to electrically connect the pair of electrodes.

Hereinafter, the semiconductor-type wind speed sensor is described with reference to the drawings.

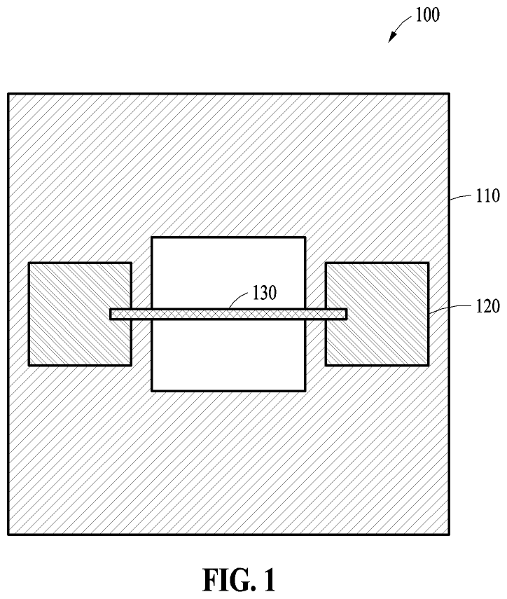

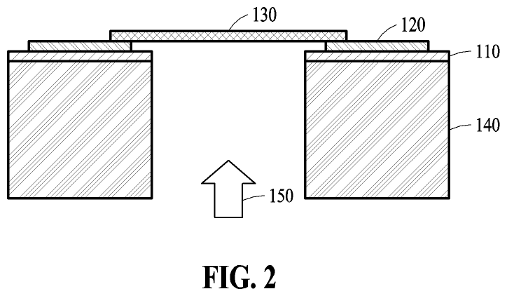

FIG. 1 is a plan view of a semiconductor-type wind speed sensor 100 according to an embodiment, and FIG. 2 is a front view of the semiconductor-type wind speed sensor 100. Referring to FIGS. 1 and 2, the semiconductor-type wind speed sensor 100 may include a substrate 110 including a through hole, a pair of electrodes 120 formed on the substrate 110, a metal wire 130 configured to electrically connect the pair of electrodes 120, and a base layer 140 configured to support the substrate 110. A portion of the base layer 140 through which an air flow 150 passes may have the same size as that of the through hole of the substrate 110, or through holes with different sizes in a portion of the substrate 110 may be formed in a portion of the base layer 140, if necessary. Referring to FIGS. 1 and 2, a direction in which the air flow 150 passes through the through hole is represented as a vertical direction, but is not limited thereto. A wind speed may be calculated from an air flow in any direction.

According to an embodiment, a substrate including a through hole and a base layer that supports the substrate may be prepared, and a pair of electrodes may be formed on the substrate using an adhesive. The pair of electrodes may face each other, and the through hole may be formed between the pair of electrodes. The pair of electrodes may have coupling portions that may attach or detach the metal wire, so that the metal wire may electrically connect the pair of electrodes. The metal wire may be formed above the through hole. When a voltage is applied to the pair of electrodes to allow a current to flow through the metal wire, a temperature of the metal wire may increase, and accordingly, a resistance value may increase. When an air flow passes through the through hole above the metal wire being in the high temperature state, the metal wire may be cooled by air cooling, so that the resistance value may be reduced and the wind speed may be calculated from a change in the resistance value. In addition, zero-point correction may be performed on a result value depending on an installation environment, to obtain an accurate value.

According to an embodiment, the through hole may be formed between the pair of electrodes. Air may flow through the through hole, and the metal wire that electrically connects the pair of electrodes may be formed above the through hole to measure the wind speed.

According to an embodiment, since the pair of electrodes having the same electrode characteristics faces each other, a uniform distribution of currents may be induced. Accordingly, problems such as a high power consumption or a heat generation phenomenon caused by non-uniform current distribution may be solved, and thus, it is possible to increase an efficiency and enhance characteristics and reliability of the electrodes.

According to an embodiment, the metal wire may be formed above the through hole.

According to an embodiment, when an air flow is formed through the through hole, the metal wire may be positioned in a direction perpendicular to the air flow and may lose heat due to the air flow, which may lead to a reduction in the resistance value.

According to an embodiment, the metal wire may include at least one of gold (Au), silver (Ag), palladium (Pd), rhodium (Rh), iridium (Ir), osmium (Os), aluminum (Al), nickel (Ni), molybdenum (Mo), platinum (Pt), tungsten (W), and tantalum (Ta).

According to an embodiment, the metal wire may have a high temperature coefficient of resistance. In addition, the metal wire may hardly be corroded and may be heated up to a high temperature, e.g., 1000° C. or greater.

According to an embodiment, the temperature of the metal wire may be relatively unaffected by a change in the ambient temperature. In addition, the metal wire may implement uniformly thin lines.

According to an embodiment, the metal wire may have a diameter of several micrometers (μm) to several millimeters (mm).

The metal wire may have a diameter of 1 μm or greater; 10 μm or greater; 30 μm or greater; 50 μm or greater; 70 μm or greater; 100 μm or greater; 300 μm or greater; 500 μm or greater; 10 mm or less; 8 mm or less; 7 mm or less; 6 mm or less; 5 mm or less; 4 mm or less; 3 mm or less; or 1 mm or less. A minimum value and a maximum value may be selected from the above-described diameters. If the diameter of the metal wire is less than 1 μm, the metal wire may be unstable when a high wind speed is measured, which may cause a malfunction. If the diameter of the metal wire exceeds 10 mm, a measured value may be inaccurate due to a different in the temperature between the inside and the outside of the metal wire.

According to an embodiment, the substrate may include at least one of silicon (Si), germanium (Ge), selenium (Se), gallium arsenide (GaAs), gallium arsenide phosphide (GaAsP), gallium nitride (GaN), silicon carbide (SiC), zinc sulfide (ZnS), silicon dioxide (SiO₂), polyimide (PI), polyetherimide (PEI), polycarbonate (PC), polyester (PES), polystyrene (PS), polyolefin (PO), polysulfone (PSF), polyarylate (PAR), polyvinyl chloride (PVC), and cellulose ester.

According to an embodiment, the substrate may be excellent in a power conversion efficiency, may quickly respond, and may be miniaturized and lightened. In addition, an energy band gap may refer to a difference between a minimum energy value of a valence band in which electrons are collected and a maximum energy value of a conduction band in which an electron is absent. As an energy band gap of the substrate increases, a voltage and temperature at which the semiconductor-type wind speed sensor operates may increase.

According to an embodiment, the substrate may further include an insulating film formed on the substrate. The insulating film may be a single layer, or a laminate of a plurality of films.

According to an embodiment, the insulating film may have a flat surface. For example, a surface of the insulating film may have an average surface roughness (Ra) of 0.5 nanometer (nm) or less, and a root mean square roughness (Rms) of 0.6 nm or less. Desirably, the average surface roughness (Ra) may be 0.3 nm or less, and the root mean square roughness (Rms) may be 0.4 nm or less.

According to an embodiment, the insulating film may have a thickness of about 50 nm to about 5000 nm.

The insulating film may have a thickness of 50 nm to 200 nm; 50 nm to 500 nm; 80 nm to 700 nm; 100 nm to 1000 nm; 150 nm to 1500 nm; 250 nm to 2000 nm; 500 nm to 3000 nm; 1000 nm to 3500 nm; 1500 nm to 4000 nm; and 2500 nm to 5000 nm. If the thickness of the insulating film is less than 50 nm, current may be leaked to the substrate. If the thickness of the insulating film exceeds 5000 nm, the degree of integration may decrease, which may result in poor performance and cause a malfunction.

According to an embodiment, the insulating film may include at least one of an oxide film, a nitride film, an oxynitride film, a nitride oxide film, a phosphosilicate glass (PSG) film, and a borophosphosilicate glass (BPSG) film.

According to an embodiment, the insulating film may include a silicon oxide film (SiOₓ), a silicon nitride film (SiNₓ), a silicon nitride oxide film (SiNₓO_{y}) (x >y), or a silicon oxide nitride film (SiOₓN_{y}) (x >y). The insulating film may function as a barrier layer to prevent impurities such as movable ions and moisture contained in a support substrate from diffusing into an electrode.

According to an embodiment, the insulating film may be formed by, for example, a chemical vapor deposition method, a sputtering method, or a plasma process.

According to an embodiment, the chemical vapor deposition method may include rapid thermal chemical vapor deposition (RTCVD), inductively coupled plasma-chemical vapor deposition (ICP-CVD), low pressure chemical vapor deposition (LPCVD), atmospheric pressure chemical vapor deposition (APCVD), metal organic chemical vapor deposition (MOCVD), and plasma-enhanced chemical vapor deposition (PECVD) method, but is not limited thereto.

According to an embodiment, the insulating film may be an oxide film formed by oxidizing the substrate. An oxidation treatment of the substrate may be performed by dry thermal oxidation, and it may be desirable to add a gas of halogen or halogen compound. Such a gas may typically include HCl, and may also include HF, NF₃, HBr, Cl₂, ClF₃, BCl₃, F₂, Br₂, and the like. In addition, the oxidation treatment of the substrate may also be performed by a surface treatment using ozone water, hydrogen peroxide solution, or water vapor.

In an embodiment, a nitride film may be formed through a thermal nitration process. For example, by providing a gas containing a nitride source to the substrate and performing a heat treatment at a high temperature, a surface of the substrate may be partially nitrified and changed to a nitride film. For example, the nitride film may be formed using ammonia (NH₃) gas, nitrogen (N₂) gas, nitrogen monoxide (NO) gas, and/or nitrous oxide (N₂O) gas. In addition, the nitride film may be formed by partially nitrifying the substrate at a temperature of about 500° C. to about 1,200° C.

According to an embodiment, the substrate may further include a mesh material.

According to an embodiment, the substrate may further include a material with a large number of pore structures, to enhance air permeability. A material with pores may be defined as a microporous material (<2 nm), a mesoporous material (2 nm to 50 nm), and a macroporous material (>50 nm) depending on the size of the pores, and may include, for example, mesoporous silica, mesoporous metal phosphorus oxide, and a mesoporous metal oxide, such as α-Fe₂O₃, γ-Fe₂O₃, Fe₃O₄, TiO₂, and In₂O₃.

According to an embodiment, an influence of wind due to the substrate may be minimized, and thus, it is possible to prevent the wind speed from increasing and to increase an accuracy of the calculated wind speed.

According to an embodiment, the substrate may have a thickness of about 50 μm to about 800 μm.

The substrate may have a thickness of 50 μm to 100 μm; 50 μm to 200 μm; 50 μm to 300 μm; 70 μm to 400 μm; 80 μm to 500 μm; 100 μm to 600 μm; 150 μm to 700 μm; 250 μm to 750 μm; and 450 μm to 800 μm. If the thickness of the substrate is less than 50 μm, it may be difficult to handle the substrate due to an increase in the risk of damage. If the thickness of the substrate exceeds 800 μm, an influence of wind passing through the substrate may increase, which may cause a problem in accurately calculating the wind speed.

According to an embodiment, the semiconductor-type wind speed sensor may control the temperature of the metal wire by allowing a current to flow through the metal wire.

According to an embodiment, a voltage may be applied to the pair of electrodes to allow current to flow through the metal wire. The voltage applied between the pair of electrodes may be alternating current (AC) or direct current (DC) alone, or may be a voltage including both DC and AC.

According to an embodiment, the electrode may include at least one of platinum (Pt), palladium (Pd), silver (Ag), gold (Au), nickel (Ni), titanium (Ti), copper (Cu), chromium (Cr), aluminum (Al), tin (Sn), molybdenum (Mo), ruthenium (Ru), and indium (In).

According to an embodiment, the pair of electrodes may have coupling portions that may attach and detach the metal wire.

According to an embodiment, the semiconductor-type wind speed sensor may calculate a wind speed from a change in a resistance value of the metal wire due to a change in the temperature of the metal wire caused by an air flow passing through the through hole.

According to an embodiment, when a current is allowed to flow through the metal wire, the temperature of the metal wire may increase, and accordingly, the resistance value may increase. When an air flow passes through the through hole above the metal wire being in the high temperature state, the metal wire may be cooled by air cooling, so that the resistance value may be reduced and the wind speed may be calculated from a change in the resistance value. In addition, to minimize an influence by a temperature, a humidity, and other conditions depending on the installation environment, zero-point correction may be performed to obtain an accurate value.

According to an embodiment, in the semiconductor-type wind speed sensor, an area of the through hole may correspond to a range of about 3% to about 70% of an area of the substrate.

The area of the through hole may be in a range of 3% to 10%; 3% to 20%; 5% to 30%; 5% to 35%; 7% to 40%; 7% to 45%; 7% to 50%; 10% to 60%; 10% to 65%; and 15% to 70% of the area of the substrate. If the area of the through hole is less than 3% of the area of the substrate, a measured value may be inaccurate due to an increase in obstruction of an air flow by the substrate. If the area of the through hole exceeds 70% of the area of the substrate, the electrodes and the metal wire may not be stably arranged.

According to an embodiment, the semiconductor-type wind speed sensor may further include an adhesive layer on the substrate.

According to an embodiment, the semiconductor-type wind speed sensor may include an adhesive layer to form the pair of electrodes on the substrate.

According to an embodiment, an adhesive that forms the adhesive layer may include various curable adhesives such as a reactive curable adhesive, a thermal curable adhesive, a photocurable adhesive such as an ultraviolet curable adhesive, and an anaerobic adhesive. Desirably, the adhesive may include a filler or powder formed of silver, nickel, aluminum, or aluminum nitride, and may also have a high thermal conductivity.

According to an embodiment, a method of manufacturing a semiconductor-type wind speed sensor may include preparing a substrate including a through hole, forming a pair of electrodes such that the through hole is between the electrodes, and electrically connecting the pair of electrodes with a wire.

In the method of manufacturing the semiconductor-type wind speed sensor, a semiconductor-type wind speed sensor with an enhanced efficiency, an increased usability, and a simple structure may be manufactured using a simple process. Thus, it is possible to supplement economical aspects and complex processes due to a high vertical structure and a formation of a vacuum cavity, which are limitations of a related art. Since the air flow becomes zero as the air flow approaches the surface, an accurate measurement may be difficult. However, the semiconductor-type wind speed sensor may measure an air flow passing by the air, instead of an air flow passing over the surface. In addition, the semiconductor-type wind speed sensor may prevent heat from escaping to the surface, to calculate a result value having a high reliability and measure even fine air flows.

While the embodiments are described above, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

What is claimed is:

1. A semiconductor-type wind speed sensor comprising:
a substrate comprising a through hole;
a pair of electrodes formed on the substrate; and
a metal wire configured to electrically connect the pair of electrodes.

2. The semiconductor-type wind speed sensor of claim 1, wherein the through hole is formed between the pair of electrodes.

3. The semiconductor-type wind speed sensor of claim 1, wherein the metal wire is formed above the through hole.

4. The semiconductor-type wind speed sensor of claim 1, wherein the metal wire comprises at least one material selected from a group consisting of gold (Au), silver (Ag), palladium (Pd), rhodium (Rh), iridium (Ir), osmium (Os), aluminum (Al), nickel (Ni), molybdenum (Mo), platinum (Pt), tungsten (W), and tantalum (Ta).

5. The semiconductor-type wind speed sensor of claim 1, wherein the metal wire has a diameter of 1 micrometer (μm) to 10 millimeters (mm).

6. The semiconductor-type wind speed sensor of claim 1, wherein the substrate comprises at least one material selected from the group consisting of silicon (Si), germanium (Ge), selenium (Se), gallium arsenide (GaAs), gallium arsenide phosphide (GaAsP), gallium nitride (GaN), silicon carbide (SiC), zinc sulfide (ZnS), silicon dioxide (SiO₂), polyimide (PI), polyetherimide (PEI), polycarbonate (PC), polyester (PES), polystyrene (PS), polyolefin (PO), polysulfone (PSF), polyarylate (PAR), polyvinyl chloride (PVC), and cellulose ester.

7. The semiconductor-type wind speed sensor of claim 1, wherein the substrate further comprises an insulating film formed on the substrate.

8. The semiconductor-type wind speed sensor of claim 7, wherein the insulating film comprises at least one material selected from a group consisting of an oxide film, a nitride film, an oxynitride film, a nitride oxide film, a phosphosilicate glass (PSG) film, and a borophosphosilicate glass (BPSG) film.

9. The semiconductor-type wind speed sensor of claim 1, wherein the substrate further comprises a mesh material.

10. The semiconductor-type wind speed sensor of claim 1, wherein the substrate has a thickness of about 50 μm to about 800 μm.

11. The semiconductor-type wind speed sensor of claim 1, wherein the semiconductor-type wind speed sensor is configured to control a temperature of the metal wire by allowing a current to flow through the metal wire.

12. The semiconductor-type wind speed sensor of claim 1, wherein the semiconductor-type wind speed sensor is configured to calculate a wind speed based on a change in a resistance value of the metal wire due to a change in a temperature of the metal wire caused by an air flow passing through the through hole.

13. The semiconductor-type wind speed sensor of claim 1, wherein an area of the through hole corresponds to a range of about 3% to about 70% of an area of the substrate.

14. The semiconductor-type wind speed sensor of claim 1, further comprising:
an adhesive layer on the substrate.

15. A method of manufacturing a semiconductor-type wind speed sensor, the method comprising:
preparing a substrate comprising a through hole;
forming a pair of electrodes such that the through hole is between the electrodes; and
electrically connecting the pair of electrodes using a wire.

16. The method of claim 15, further comprising connecting the wire above the through hole.

17. The method of claim 15, wherein the wire comprises at least one material selected from a group consisting of gold (Au), silver (Ag), palladium (Pd), rhodium (Rh), iridium (Ir), osmium (Os), aluminum (Al), nickel (Ni), molybdenum (Mo), platinum (Pt), tungsten (W), and tantalum (Ta).

18. The method of claim 15, wherein the wire has a diameter of 1 micrometer (μm) to 10 millimeters (mm).

19. The method of claim 15, further comprising configuring the semiconductor-type wind speed sensor to control a temperature of the wire by allowing a current to flow through the wire.

20. The method of claim 15, further comprising configuring the semiconductor-type wind speed sensor to calculate a wind speed based on a change in a resistance value of the wire due to a change in a temperature of the wire caused by an air flow passing through the through hole.
